(19) United States
(12) Patent Application Publication
(10) Pub. No.: US 2025/0324600 A1
(43) Pub. Date: Oct. 16, 2025

(54) SONOS MEMORY ELEMENT AND MANUFACTURING METHOD THEREOF

(71) Applicant: Powerchip Semiconductor Manufacturing Corporation, Hsinchu (TW)

(72) Inventor: Wen-Yueh Chang, Hsinchu City (TW)

(73) Assignee: Powerchip Semiconductor Manufacturing Corporation, Hsinchu (TW)

(21) Appl. No.: 18/666,809

(22) Filed: May 16, 2024

(30) Foreign Application Priority Data
Apr. 12, 2024 (TW) 113113792

(51) Int. Cl. H10B 43/30

(52) U.S. Cl. CPC H10B 43/30

(57) ABSTRACT

A SONOS memory element includes a substrate, source lines formed in the substrate, a semiconductor epitaxial layer formed on the substrate, element isolation structures, trenches, gates, oxide-nitride-oxide (ONO) stack layers, drain regions, and bit lines. The element isolation structures are formed in the semiconductor epitaxial layer and extend along a first direction to define multiple active regions therein. The trenches are formed in the semiconductor epitaxial layer and span the element isolation structures along a second direction, wherein a bottom of each of the trenches exposes a part of each of the source lines. The gate is disposed in the trench, and the ONO stack layer is located between the gate and the trench. The drain regions are formed in the active regions on both sides of each of the gates. The bit lines are located on the semiconductor epitaxial layer and are electrically connected to the drain regions.

### CROSS-REFERENCE TO RELATED APPLICATION

This application claims the priority benefit of Taiwan application serial no. 113113792, filed on Apr. 12, 2024. The entirety of the above-mentioned patent application is hereby incorporated by reference herein and made a part of this specification.

### BACKGROUND

### Technical Field

The disclosure relates to a flash memory technology, and in particular to a silicon-oxide-nitride-oxide-silicon (SONOS) memory element and a manufacturing method thereof.

### Description of Related Art

Since the non-volatile memory (NVM) has the advantage that stored data does not disappear after a power outage, many electrical products must be equipped with this type of memory to maintain normal operation when the electrical products are turned on.

The SONOS NOR flash memory is the simplest NVM element and may store programming charge into oxide-nitride-oxide (ONO) gate dielectric. However, due to the severe short channel effect (SCE) caused by the thicker equivalent ONO gate dielectric thickness, it is difficult to reduce the size of the SONOS memory element (in the channel length direction).

### SUMMARY

The disclosure provides a SONOS memory element, which can maintain a channel length while the element is continuously shrinking, thereby preventing a short channel effect.

The disclosure also provides a manufacturing method of a SONOS memory element, which can manufacture the non-volatile memory element.

A SONOS memory element of the disclosure includes a substrate, multiple source lines formed in the substrate, a semiconductor epitaxial layer formed on the substrate, multiple element isolation structures, multiple trenches, multiple gates, an oxide-nitride-oxide (ONO) stack layer, multiple drain regions, and multiple bit lines. The element isolation structures are formed in the semiconductor epitaxial layer and extend along a first direction to define multiple active regions therein. The trenches are formed in the semiconductor epitaxial layer and span the element isolation structures along a second direction. A bottom of each of the trenches exposes a part of each of the source lines. The gate is located in the trench. The ONO stack layer is located between the gate and the trench. The drain regions are formed in the active regions on both sides of each of the gates. The bit lines are located on the semiconductor epitaxial layer and are electrically connected to the drain regions.

In an embodiment of the disclosure, the bit line is perpendicular to the source line, the bit line is perpendicular to the gate, and the source line is parallel to the gate.

In an embodiment of the disclosure, in a top view, each of the source lines overlaps with each of the gates.

In an embodiment of the disclosure, in a top view, the source line is disposed on both sides of each of the gates.

In an embodiment of the disclosure, the bit line is not parallel to the source line, the bit line is not parallel to the gate, and the source line is perpendicular to the gate.

In an embodiment of the disclosure, in a top view, an angle is formed between the bit line and the source line, and the angle is between 20° and 60°.

In an embodiment of the disclosure, a top of the gate is lower than a top of the trench.

In an embodiment of the disclosure, a part of the trench intersecting with the element isolation structure has a first depth, a part of the trench not intersecting with the element isolation structure has a second depth, and the second depth is greater than the first depth.

In an embodiment of the disclosure, the bit line is in direct contact with the drain region.

A manufacturing method of a SONOS memory element of the disclosure includes the following steps. Multiple source lines are formed in a substrate. A semiconductor epitaxial layer is formed on the substrate. Multiple element isolation structures extending along a first direction are formed in the semiconductor epitaxial layer to define multiple active regions in the semiconductor epitaxial layer. Multiple trenches are formed in the semiconductor epitaxial layer. The trenches span the element isolation structures along a second direction. A bottom of each of the trenches exposes a part of each of the source lines. An oxide-nitride-oxide (ONO) stack layer is formed on a surface of the trenches. Multiple gates are formed in the trenches. Multiple drain regions are formed in the active regions on both sides of each of the gates. Multiple bit lines are formed on the semiconductor epitaxial layer. The bit lines are electrically connected to the drain regions.

In another embodiment of the disclosure, the step of forming the source line includes forming the source lines extending along the first direction or the second direction.

In another embodiment of the disclosure, the step of forming the source lines extending along the second direction includes forming the source lines directly below or in the substrate on both sides of each of the gates.

In another embodiment of the disclosure, the step of forming the bit lines includes forming the bit lines extending along the first direction or a third direction.

In another embodiment of the disclosure, an angle is formed between the third direction and the second direction, and the angle is between 20° and 60°.

In another embodiment of the disclosure, the manufacturing method after forming the gates may further include filling a dielectric layer in the trenches.

In another embodiment of the disclosure, the method of forming the trenches in the semiconductor epitaxial layer includes the following steps. The semiconductor epitaxial layer and the element isolation structures are dry etched, and a part of the trenches intersecting with the element isolation structures is enabled to have a first depth and a part not intersecting with the element isolation structures is enabled to have a second depth using an etching selectivity ratio of the semiconductor epitaxial layer and the element isolation structures. The second depth is greater than the first depth.

In another embodiment of the disclosure, the method of forming the gates includes the following steps. A conductor material filling the trenches is formed on the semiconductor epitaxial layer. The conductor material other than the trenches is removed using a planarization process. A part of the conductor material is then etched, so that a top of the gates is lower than a top of the trenches.

In another embodiment of the disclosure, the bit line is in direct contact with the drain region.

In order for the features and advantages of the disclosure to be more comprehensible, the following specific embodiments are described in detail in conjunction with the drawings.

### BRIEF DESCRIPTION OF THE DRAWINGS

FIG. 1A is a top view of a SONOS memory element according to a first embodiment of the disclosure.

FIG. 1B is a schematic cross-sectional view of the SONOS memory element along a line segment B-B′ in FIG. 1A.

FIG. 1C is a schematic cross-sectional view of the SONOS memory element along a line segment C-C′ in FIG. 1A.

FIG. 2A is a top view of a SONOS memory element according to a second embodiment of the disclosure.

FIG. 2B is a schematic cross-sectional view of the SONOS memory element along a line segment B-B′ in FIG. 2A.

FIG. 3A is a top view of a SONOS memory element according to a third embodiment of the disclosure.

FIG. 3B is a schematic cross-sectional view of the SONOS memory element along a line segment B-B′ in FIG. 3A.

FIG. 3C is a schematic cross-sectional view of the SONOS memory element along a line segment C-C′ in FIG. 3A.

FIG. 4A to FIG. 4F are schematic cross-sectional views of a manufacturing process of the SONOS memory element according to a fourth embodiment of the disclosure, corresponding to the line segment B-B′ in FIG. 1A.

FIG. 5A to FIG. 5F are schematic cross-sectional views of the manufacturing process of the SONOS memory element of the fourth embodiment, corresponding to the line segment C-C′ in FIG. 1A.

FIG. 6A to FIG. 6F are schematic cross-sectional views of a manufacturing process of a SONOS memory element according to a fifth embodiment of the disclosure, corresponding to the line segment B-B′ in FIG. 3A.

FIG. 7A to FIG. 7F are cross-sectional schematic views of the manufacturing process of the SONOS memory element of the fifth embodiment, corresponding to the line segment C-C′ in FIG. 3A.

### DESCRIPTION OF THE EMBODIMENTS

The disclosure can be understood by referring to the following detailed description in conjunction with the drawings. It should be noted that in order for readers to easily understand and for the simplicity of the drawings, multiple drawings in the disclosure only depict a part of an electronic device, and specific elements in the drawings are not drawn to actual scale. In addition, the number and the size of elements in the drawings are only for illustration and are not intended to limit the scope of the disclosure. Furthermore, directional terms such as “upper” and “lower” mentioned herein are only used to refer to the direction of the drawings and are not used to limit the disclosure. In the following description and claims, “include” or similar words shall be interpreted to mean “comprising but not limited to . . . ”.

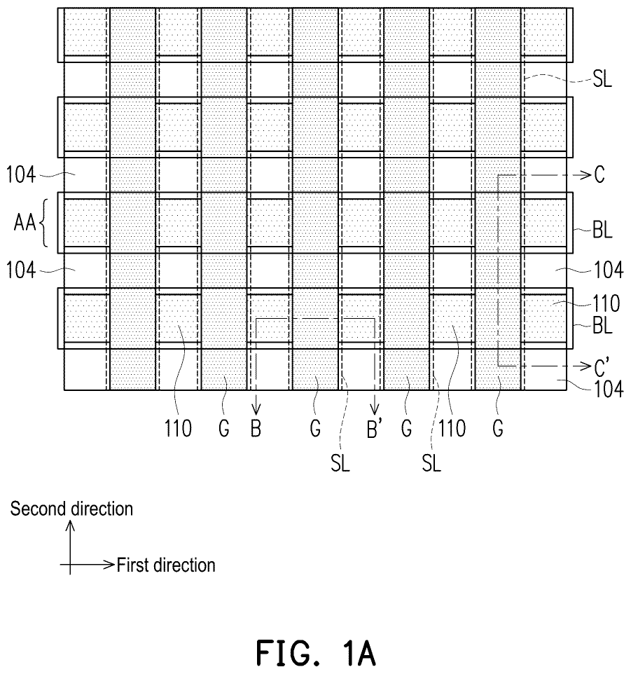

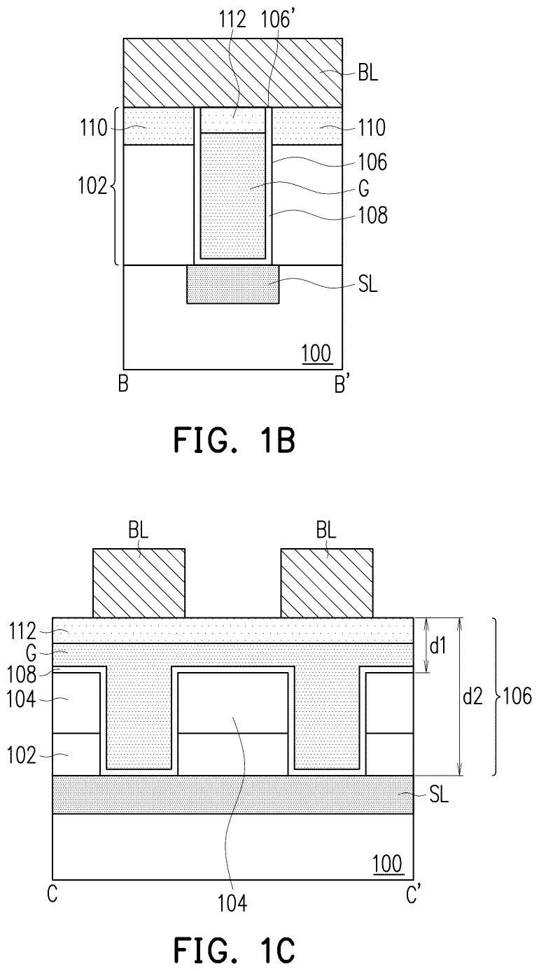

FIG. 1A is a top view of a SONOS memory element according to a first embodiment of the disclosure. FIG. 1B is a schematic cross-sectional view of the SONOS memory element along a line segment B-B′ in FIG. 1A. FIG. 1C is a schematic cross-sectional view of the SONOS memory element along a line segment C-C′ in FIG. 1A.

Please refer to FIG. 1A to FIG. 1C at the same time. The SONOS memory element of the first embodiment includes a substrate 100, a source line SL formed in the substrate 100, a semiconductor epitaxial layer 102 formed on the substrate 100, an element isolation structure 104, a trench 106, a gate G (as a word line), an oxide-nitride-oxide (ONO) stack layer 108, a drain region 110, and a bit line BL. In an embodiment, the substrate 100 includes a silicon substrate, and the semiconductor epitaxial layer 102 includes a silicon epitaxial layer.

Please refer to FIG. 1A and FIG. 1C at the same time. Multiple element isolation structures 104 are formed in the semiconductor epitaxial layer 102 and extend along a first direction to define multiple active regions AA therein. Therefore, the active regions AA and the element isolation structures 104 all extend along the first direction and are staggered with each other. In an embodiment, the thickness of the semiconductor epitaxial layer 102 may be greater than the thickness of the element isolation structure 104, so the element isolation structure 104 is not in contact with the source line SL.

Please refer to FIG. 1B and FIG. 1C at the same time. Multiple trenches 106 are formed in the semiconductor epitaxial layer 102 and span the element isolation structures 104 along a second direction. A bottom of the trench 106 exposes a part of each of the source lines SL. In the first embodiment, the source line SL is perpendicular to the bit line BL, that is, from the top view (FIG. 1A), the source line SL extends along the second direction, while the bit line BL extends along the first direction, and each of the source lines SL overlaps with each of the gates G, so each cell may be programmed and read through the bit line BL via channels on the left side and the right side of the trench 106, and the channel length is the vertical distance from the drain region 110 to the source line SL. In addition, the trench 106 itself has different depths, wherein a part that intersects with the element isolation structure 104 has a first depth d1, while a part that does not intersect with the element isolation structure 104 has a second depth d2, and the second depth d2 is greater than the first depth d1. Such structural features may be achieved through the etching selectivity ratio of the element isolation structure 104 and the semiconductor epitaxial layer 102. For example, an etchant (or a gas) that has a high etching rate for the semiconductor epitaxial layer 102 but a low etching rate for the element isolation structure 104 is used during the process of forming the trench 106, so as shown in FIG. 1C, the part without the element isolation structure 104 is etched until the bottom of the trench 106 exposes the source line SL, and for the part with the element isolation structure 104, the etching rate is reduced, so that there is still a part of the element isolation structure 104 at the bottom of the trench 106.

Please refer to FIG. 1A to FIG. 1C at the same time. The gate G is located in the trench 106, and the ONO stack layer 108 is located between the gate G and the trench 106. Multiple drain regions 110 are formed in the active regions AA on both sides of each of the gates G, so the drain regions 110 are surrounded by the gates G and the surrounding element isolation structures 104. Multiple bit lines BL are located on the semiconductor epitaxial layer 102 and are electrically connected to the drain regions 110. For example, the bit line BL is in direct contact with the drain region 110. In the first embodiment, the bit line BL is perpendicular to the gate G, and the source line SL is parallel to the gate G. In FIG. 1B, a top of the gate G is lower than a top 106′ of the trench 106 to electrically isolate the gate G from the bit line BL above through filling the dielectric layer 112 in the trench 106 between the gate G and the bit line BL, while separating the bit line BL and the drain region 110, and the bit line BL and the drain region 110 are connected through a conductive plug such as a via formed in the dielectric layer, wherein the dielectric layer 112 is, for example, an oxide layer. However, the disclosure is not limited thereto. In another embodiment, the top of the gate G may be flush with the top 106′ of the trench 106, and the gate G and the bit line BL are separated through another dielectric layer (not shown) formed entirely over the semiconductor epitaxial layer 102. In FIG. 1B, the ONO stack layer 108 may further extend between the gate G and the drain region 110.

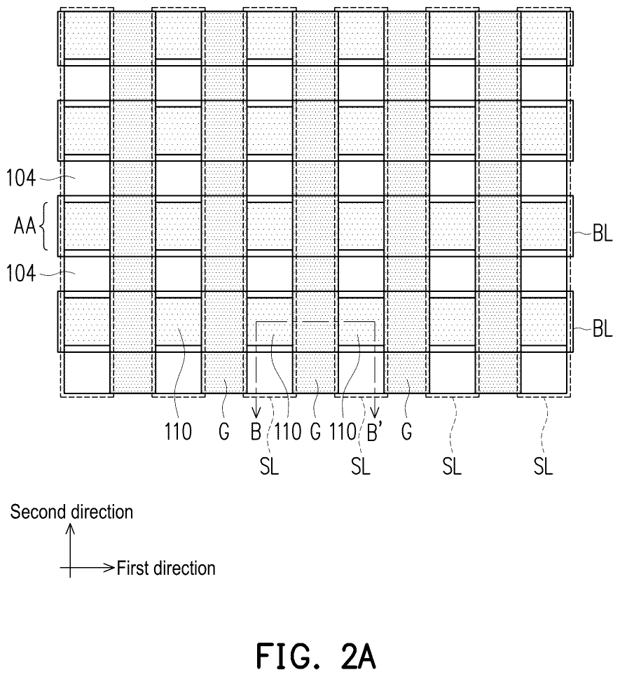

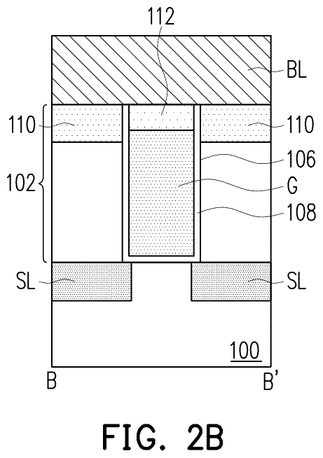

FIG. 2A is a top view of a SONOS memory element according to a second embodiment of the disclosure. FIG. 2B is a schematic cross-sectional view of the SONOS memory element along a line segment B-B′ in FIG. 2A. In FIG. 2A and FIG. 2B, the same reference numerals as those in the first embodiment are used to represent the same or similar parts and components, and reference may also be made to the content of the first embodiment for the relevant content of the same or similar parts and components, which will not be described again.

Please refer to FIG. 2A and FIG. 2B at the same time. The difference between this embodiment and the first embodiment is that in the top view (FIG. 2A), the source lines SL are disposed on both sides of each of the gates G. In other words, each of the source lines SL overlaps with multiple drain regions 110 on one side of the same gate G along the second direction. Therefore, cells located on the left side (of the trench 106) and cells on the right may be respectively programmed and read via the source lines SL on both sides (the left side and the right side).

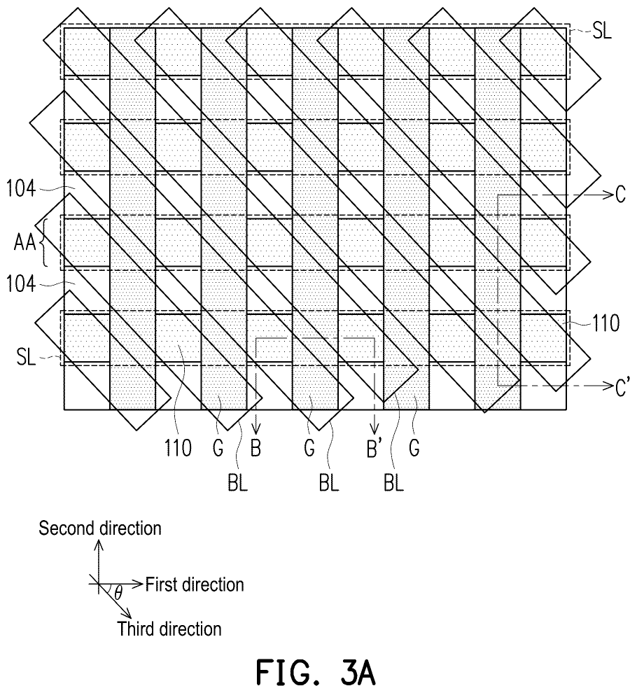

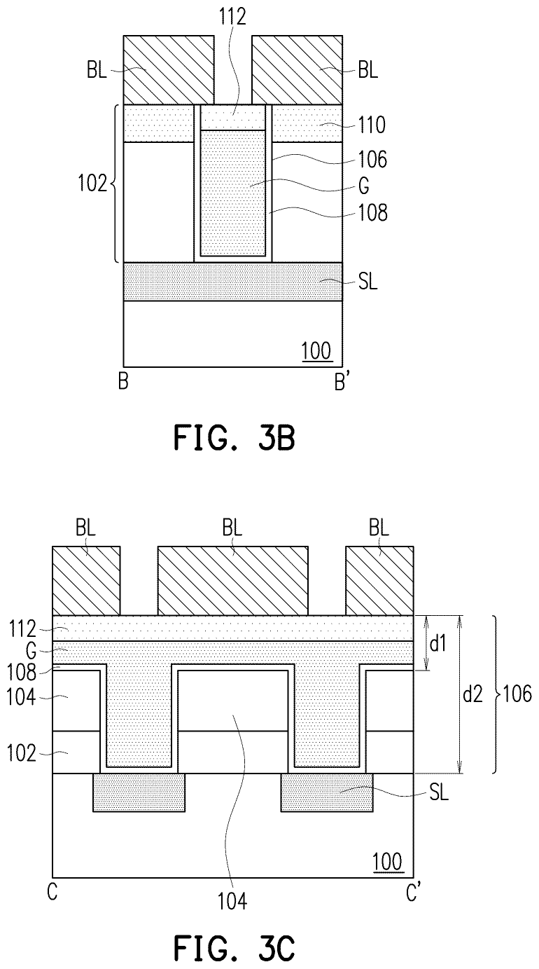

FIG. 3A is a top view of a SONOS memory element according to a third embodiment of the disclosure. FIG. 3B is a schematic cross-sectional view of the SONOS memory element along a line segment B-B′ in FIG. 3A. FIG. 3C is a schematic cross-sectional view of the SONOS memory element along a line segment C-C′ in FIG. 3A. In FIG. 3A to FIG. 3C, the same reference numerals as those in the first embodiment are used to represent the same or similar parts and components, and reference may also be made to the content of the first embodiment for the relevant content of the same or similar parts and components, which will not be described again.

Please refer to FIG. 3A to FIG. 3C at the same time. The difference between this embodiment and the first embodiment is that the bit line BL is not parallel to the source line SL, the bit line is not parallel to the gate G, and the source line SL is perpendicular to the gate G. Therefore, cells on the left side and cells on the right side of the same word line (that is, the gate G) may be respectively programmed and read via different bit lines BL. In the top view of this embodiment (FIG. 3), the source line SL extends along the first direction, the bit line BL extends along a third direction and forms an angle θ with the source line SL, and the angle θ is, for example, between 20° and 60°. However, the disclosure is not limited thereto. The angle θ mainly depends on the spacing/width between the above lines, as long as a single bit line BL can span two drain regions 110 on different sides of the same gate G.

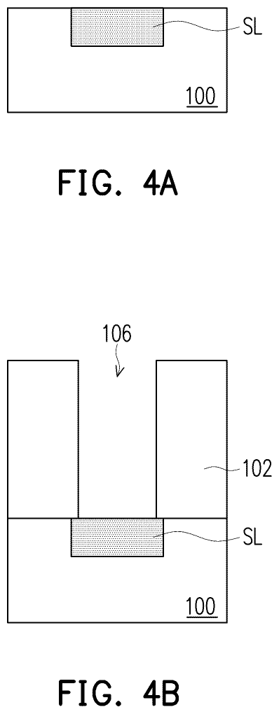

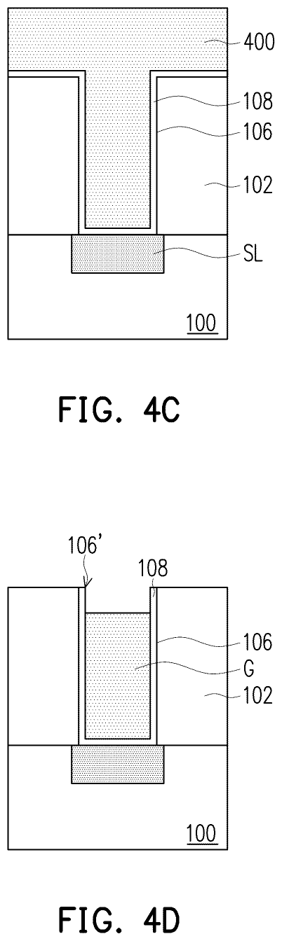

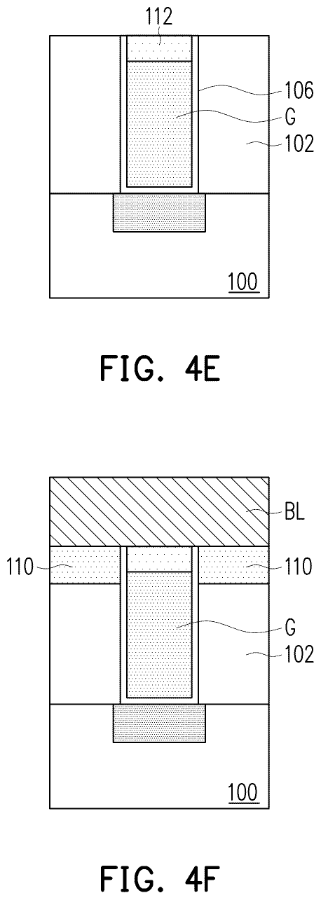

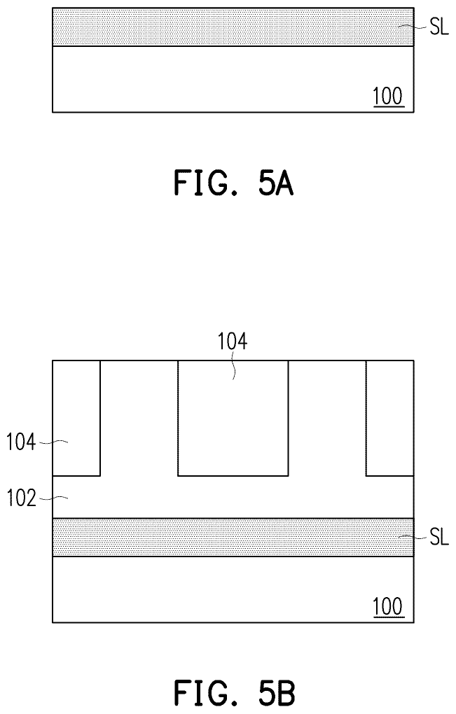

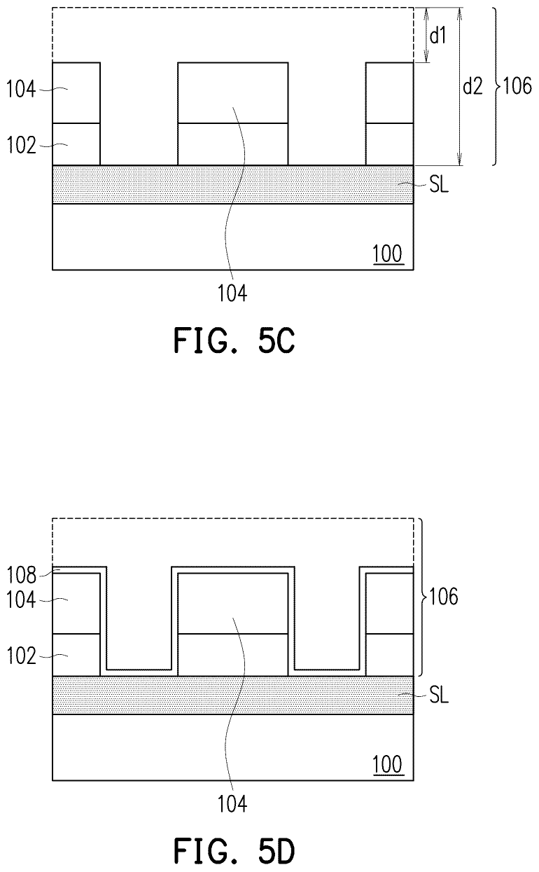

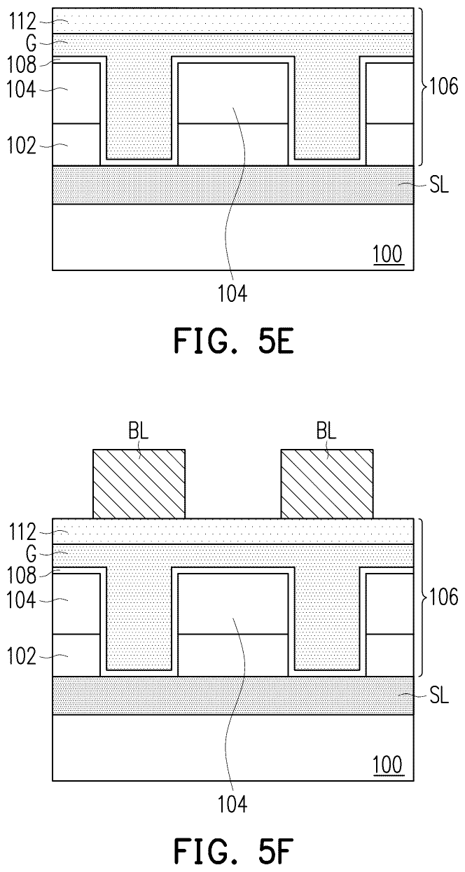

FIG. 4A to FIG. 4F are schematic cross-sectional views of a manufacturing process of the SONOS memory element according to a fourth embodiment of the disclosure, corresponding to the line segment B-B′ in FIG. 1A. FIG. 5A to FIG. 5F are schematic cross-sectional views of the manufacturing process of the SONOS memory element of the fourth embodiment, corresponding to the line segment C-C′ in FIG. 1A. In the fourth embodiment, the same reference numerals as those in the first embodiment are used to represent the same or similar parts and components, and reference may also be made to the content of the first embodiment for the relevant content of the same or similar parts and components, which will not be described again.

Please refer to FIG. 4A and FIG. 5A at the same time. First, multiple source lines SL are formed in the substrate 100. The step of forming the source lines SL includes forming the source lines SL extending along the second direction. In addition, the source lines SL extending along the second direction may be formed directly below each of the gates G as shown in FIG. 1A or the source lines SL may be formed in the substrate 100 on both sides of the gate G as shown in FIG. 2A of the second embodiment.

Then, please refer to FIG. 5B. The semiconductor epitaxial layer 102 is formed on the substrate 100, and multiple element isolation structures 104 extending along the first direction are formed in the semiconductor epitaxial layer 102 to define multiple active regions in the semiconductor epitaxial layer 102. The manner of forming the element isolation structure 104 is, for example, but not limited to, first forming multiple channels extending along the first direction in the semiconductor epitaxial layer 102, then filling an insulating material therein, and removing excess insulating material above the semiconductor epitaxial layer 102 through a planarization process (for example, chemical mechanical planarization (CMP)).

Next, please refer to FIG. 4B and FIG. 5C at the same time. The trench 106 is formed in the semiconductor epitaxial layer 102, and the bottom of the trench 106 exposes a part of the source line SL. In FIG. 5C, the trench 106 spans the element isolation structures 104 along the second direction, and the position of the trench 106 is indicated by a dotted line. The method of forming the trench 106 in the semiconductor epitaxial layer 102 is, for example, dry etching the semiconductor epitaxial layer 102 and the element isolation structure 104, and enabling the part of the trench 106 intersecting with the element isolation structure 104 to have the first depth d1 and the part not intersecting with the element isolation structure 104 to have the second depth d2 using the etching selectivity ratio of the semiconductor epitaxial layer 102 and the element isolation structure 104, and the second depth d2 is greater than the first depth d1.

Subsequently, please refer to FIG. 5D. The oxide-nitride-oxide (ONO) stack layer 108 is formed on a surface of the trench 106, wherein the method of forming the ONO stack layer 108 is, for example, but not limited to, first conformally depositing the ONO stack layer 108 on a side surface of the trench 106, a surface of an exposed part of the source line SL, and a surface of the semiconductor epitaxial layer 102.

Then, please refer to FIG. 4C. A conductor material 400 filling the trench 106 is formed on the semiconductor epitaxial layer 102, wherein the conductor material 400 is, for example, polycrystalline silicon.

Then, please refer to FIG. 4D. The conductor material other than the trench 106 is removed using a planarization process, and a part of the conductor material is then etched, so that a top thereof is lower than the top 106′ of the trench 106 to form multiple gates G in the trench 106. However, the disclosure is not limited thereto. The top of the gate G may also be flush with the top 106′ of the trench 106. At the same time, during the process of forming the gate G, the ONO stack layer 108 on the surface of the semiconductor epitaxial layer 102 may be removed, and the ONO stack layer 108 on the side surface of the trench 106 may be retained.

Next, please refer to FIG. 4E and FIG. 5E at the same time. The dielectric layer 112 may be filled in the trench 106 after forming the gate G to electrically isolate other lines.

Then, please refer to FIG. 4F and FIG. 5F at the same time. Multiple drain regions 110 are formed in the active regions on both sides of the gate G. The method of forming the drain region 110 is, for example, an ion implantation process, and a photomask process is not required, that is, the drain region 110 may be directly formed in the surface of the exposed semiconductor epitaxial layer 102. Then, the bit line BL is formed on the semiconductor epitaxial layer 102, wherein the bit line BL is in direct contact with the drain region 110. However, the disclosure is not limited thereto. In another embodiment, another dielectric layer (not shown) covering the drain region 110 may be first formed on the semiconductor epitaxial layer 102, and a conductive plug such as a via (not shown) connecting the bit line BL and the drain region 110 is then formed in the dielectric layer. The step of forming the bit lines BL includes forming the bit lines BL extending along the first direction.

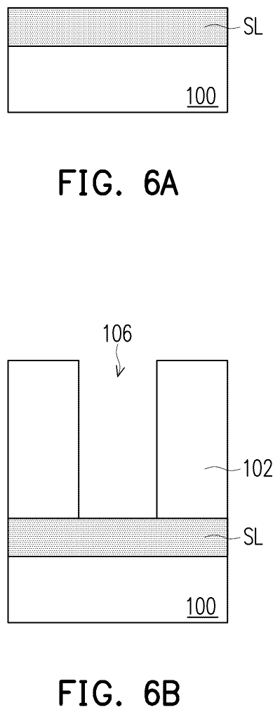

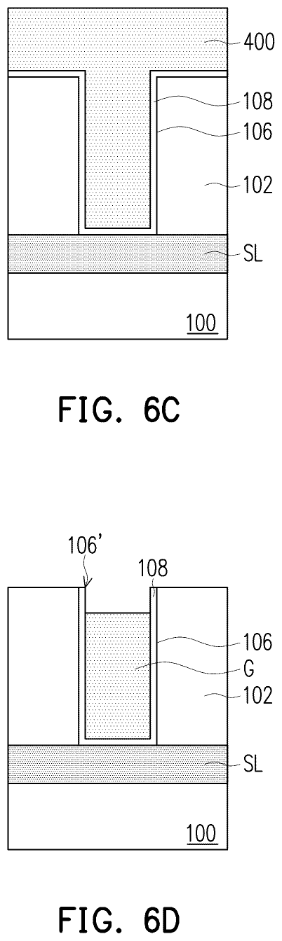

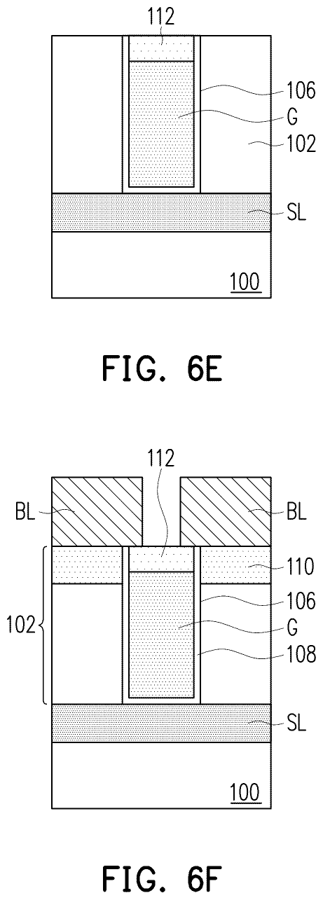

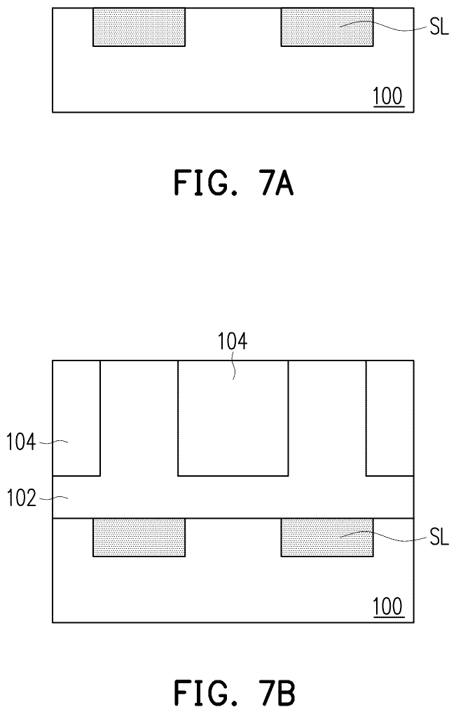

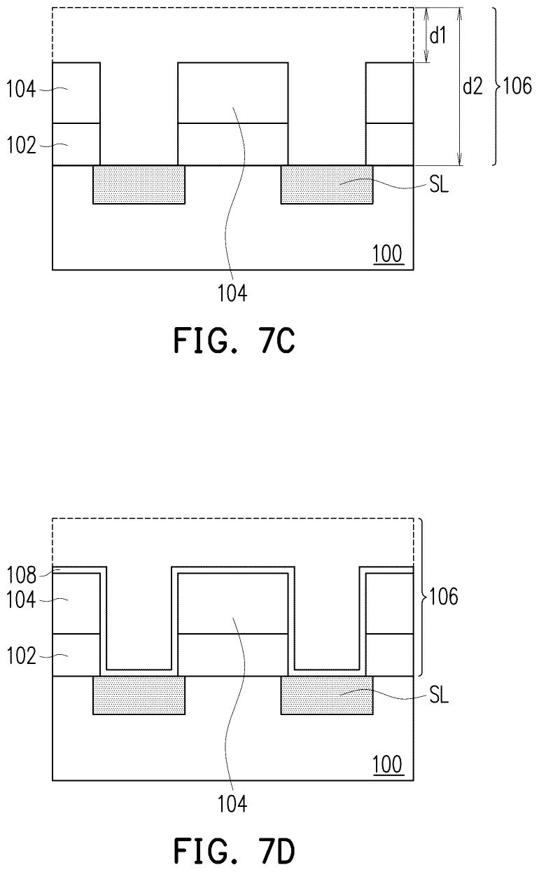

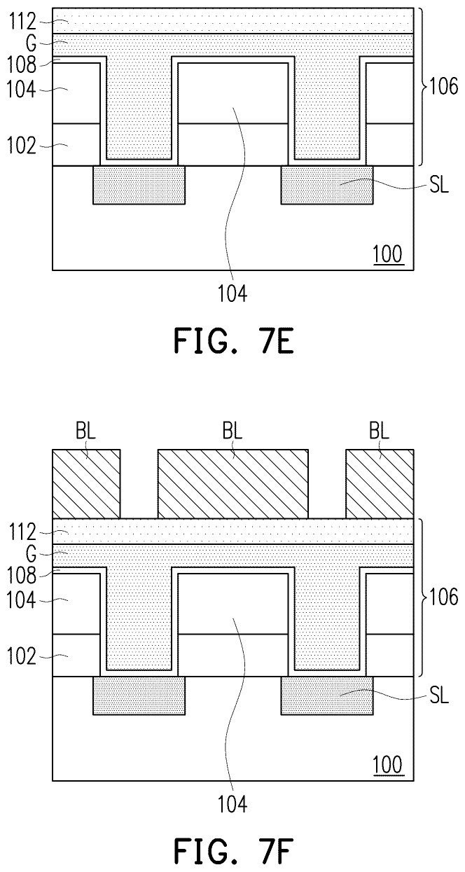

FIG. 6A to FIG. 6F are schematic cross-sectional views of a manufacturing process of a SONOS memory element according to a fifth embodiment of the disclosure, corresponding to the line segment B-B′ in FIG. 3A. FIG. 7A to FIG. 7F are cross-sectional schematic views of the manufacturing process of the SONOS memory element of the fifth embodiment, corresponding to the line segment C-C′ in FIG. 3A. In the fifth embodiment, the same reference numerals as those in the third embodiment are used to represent the same or similar parts and components, and reference may also be made to the content of the third embodiment for the relevant content of the same or similar parts and components, which will not be described again.

Please refer to FIG. 6A and FIG. 7A at the same time. First, multiple source lines SL are formed in the substrate 100. The step of forming the source lines SL includes forming the source lines SL extending along the first direction.

Then, please refer to FIG. 7B. The semiconductor epitaxial layer 102 is formed on the substrate 100, and multiple element isolation structures 104 extending along the first direction are formed in the semiconductor epitaxial layer 102 to define multiple active regions in the semiconductor epitaxial layer 102. Reference may be made to the fourth embodiment for the method of forming the element isolation structures 104.

Next, please refer to FIG. 6B and FIG. 7C at the same time. The trench 106 is formed in the semiconductor epitaxial layer 102. The bottom of the trench 106 exposes a part of the source line SL. In FIG. 7C, the trench 106 spans the element isolation structures 104 along the second direction, and the position of the trench 106 is indicated by a dotted line. Reference may be made to the fourth embodiment for the method of forming the trench 106 in the semiconductor epitaxial layer 102. Therefore, the second depth d2 of the part of the trench 106 not intersecting with the element isolation structure 104 is greater than the first depth d1 of the part of the trench 106 intersecting with the element isolation structure 104.

Subsequently, please refer to FIG. 7D. The oxide-nitride-oxide (ONO) stack layer 108 is formed on the surface of the trench 106. Reference may be made to the fourth embodiment for the method of forming the ONO stack layer 108.

Then, please refer to FIG. 6C. The conductor material 400 filling the trench 106 is formed on the semiconductor epitaxial layer 102, wherein the conductor material 400 is, for example, polycrystalline silicon.

Then, please refer to FIG. 6D. The conductor material other than the trench 106 is removed using a planarization process, and a part of the conductor material is then etched, so that a top thereof is lower than the top 106′ of the trench 106 to form multiple gates G in the trench 106. However, the disclosure is not limited thereto. The top of the gate G may also be flush with the top 106′ of the trench 106. At the same time, during the process of forming the gate G, the ONO stack layer 108 on the surface of the semiconductor epitaxial layer 102 may be removed, and the ONO stack layer 108 on the side surface of the trench 106 may be retained.

Next, please refer to FIG. 6E and FIG. 7E at the same time. After forming the gate G, the dielectric layer 112 may be filled in the trench 106 to electrically isolate other lines.

Then, please refer to FIG. 6F and FIG. 7F at the same time. Multiple drain regions 110 are formed in the active regions on both sides of the gate G, and the bit line BL is then formed on the semiconductor epitaxial layer 102, wherein the bit line BL is in direct contact with the drain region 110. In another embodiment, another dielectric layer (not shown) covering the drain region 110 may be first formed on the semiconductor epitaxial layer 102, and a conductive plug such as a via (not shown) connecting the bit line BL and the drain region 110 is then formed in the dielectric layer. The step of forming the bit lines BL includes forming the bit lines BL extending along the third direction, for example, as shown in FIG. 3A. An angle between the third direction and the second direction may be between 20° and 60°.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A SONOS memory element, comprising:
a substrate;
a plurality of source lines, formed in the substrate;
a semiconductor epitaxial layer, formed on the substrate;
a plurality of element isolation structures, formed in the semiconductor epitaxial layer and extending along a first direction to define a plurality of active regions in the semiconductor epitaxial layer;
a plurality of trenches, formed in the semiconductor epitaxial layer and spanning the element isolation structures along a second direction, wherein a bottom of each of the trenches exposes a part of each of the source lines;
a plurality of gates, respectively located in the trenches;
an oxide-nitride-oxide (ONO) stack layer, located between each of the gates and each of the trenches;
a plurality of drain regions, formed in the active regions on both sides of each of the gates; and
a plurality of bit lines, located on the semiconductor epitaxial layer and electrically connected to the drain regions.

2. The SONOS memory element according to claim 1, wherein the bit lines are perpendicular to the source lines, the bit lines are perpendicular to the gates, and the source lines are parallel to the gates.

3. The SONOS memory element according to claim 2, wherein in a top view, each of the source lines overlaps with each of the gates.

4. The SONOS memory element according to claim 2, wherein in a top view, the source lines are disposed on both sides of each of the gates.

5. The SONOS memory element according to claim 1, wherein the bit lines are not parallel to the source lines, the bit lines are not parallel to the gates, and the source lines are perpendicular to the gates.

6. The SONOS memory element according to claim 5, wherein in a top view, an angle is formed between the bit lines and the source lines, and the angle is between 20° and 60°.

7. The SONOS memory element according to claim 1, wherein a top of the gates is lower than a top of the trenches.

8. The SONOS memory element according to claim 1, wherein a part of the trenches intersecting with the element isolation structures has a first depth, a part of the trenches not intersecting with the element isolation structures has a second depth, and the second depth is greater than the first depth.

9. The SONOS memory element according to claim 1, wherein the bit lines are in direct contact with the drain regions.

10. A manufacturing method of a SONOS memory element, comprising:
forming a plurality of source lines in the substrate;
forming a semiconductor epitaxial layer on the substrate;
forming a plurality of element isolation structures extending along a first direction in the semiconductor epitaxial layer to define a plurality of active regions in the semiconductor epitaxial layer;
forming a plurality of trenches in the semiconductor epitaxial layer, wherein the trenches span the element isolation structures along a second direction, and a bottom of each of the trenches exposes a part of each of the source lines;
forming an oxide-nitride-oxide (ONO) stack layer on a surface of the trenches;
forming a plurality of gates in the trenches;
forming a plurality of drain regions in the active regions on both sides of each of the gates; and
forming a plurality of bit lines on the semiconductor epitaxial layer, wherein the bit lines are electrically connected to the drain regions.

11. The manufacturing method of the SONOS memory element according to claim 10, wherein the step of forming the source lines comprises: forming the source lines extending along the first direction or the second direction.

12. The manufacturing method of the SONOS memory element according to claim 11, wherein the step of forming the source lines extending along the second direction comprises: forming the source lines directly below or in the substrate on both sides of each of the gates.

13. The manufacturing method of the SONOS memory element according to claim 10, wherein the step of forming the bit lines comprises: forming the bit lines extending along the first direction or a third direction.

14. The manufacturing method of the SONOS memory element according to claim 13, wherein an angle is formed between the third direction and the second direction, and the angle is between 20° and 60°.

15. The manufacturing method of the SONOS memory element according to claim 10, wherein the manufacturing method after forming the gates further comprises: filling a dielectric layer in the trenches.

16. The manufacturing method of the SONOS memory element according to claim 10, wherein the method of forming the trenches in the semiconductor epitaxial layer comprises:
dry etching the semiconductor epitaxial layer and the element isolation structures, and enabling a part of the trenches intersecting with the element isolation structures to have a first depth and a part not intersecting with the element isolation structures to have a second depth using an etching selectivity ratio of the semiconductor epitaxial layer and the element isolation structures, wherein the second depth is greater than the first depth.

17. The manufacturing method of the SONOS memory element according to claim 10, wherein the method of forming the gates comprises:
forming a conductor material filling the trenches on the semiconductor epitaxial layer;
removing the conductor material other than the trenches using a planarization process; and
etching a part of the conductor material, so that a top of the gates is lower than a top of the trenches.

18. The manufacturing method of the SONOS memory element according to claim 10, wherein the bit lines are in direct contact with the drain regions.
